(19) United States
(12) Patent Application Publication
(10) Pub. No.: US 2025/0031365 A1
(43) Pub. Date: Jan. 23, 2025

(54) MEMORY STRUCTURE AND MANUFACTURING METHOD THEREOF

(71) Applicant: United Microelectronics Corp., Hsinchu (TW)

(72) Inventors: Hsin-Chieh Lin, Kaohsiung City (TW); Po-Jui Chiang, Changhua County (TW); Pei Lun Jheng, Tainan City (TW); Chao-Sheng Cheng, Taichung City (TW); Ming-Jen Chang, Hsinchu City (TW); Ko Chin Chang, Hsinchu City (TW); Yu Ming Liu, Miaoli County (TW)

(73) Assignee: United Microelectronics Corp., Hsinchu (TW)

(21) Appl. No.: 18/365,245

(22) Filed: Aug. 4, 2023

(30) Foreign Application Priority Data
Jul. 18, 2023 (TW) 112126664

(51) Int. Cl. H10B 41/30; H01L 21/28; H01L 29/423

(52) U.S. Cl. CPC H10B 41/30; H01L 29/40114; H01L 29/42328

(57) ABSTRACT

A memory structure including a substrate, charge storage layers, and a gate is provided. The charge storage layers are located on the substrate. The gate is located on the substrate on one side of the charge storage layers. The gate extends along a first direction. The gate has a protruding portion protruding along a second direction. The second direction intersects the first direction. The protruding portion is located between two adjacent charge storage layers arranged along the first direction.

### CROSS-REFERENCE TO RELATED APPLICATION

This application claims the priority benefit of Taiwan application serial no. 112126664, filed on Jul. 18, 2023. The entirety of the above-mentioned patent application is hereby incorporated by reference herein and made a part of this specification.

### BACKGROUND

### Technical Field

The invention relates to a semiconductor structure and a manufacturing method thereof, and particularly relates to a memory structure and a manufacturing method thereof.

### Description of Related Art

Since the non-volatile memory has the advantage that the stored data will not disappear even after being powered off, many electronic products must require this type of memory to maintain normal operation when the electronic products are turned on. However, how to improve the electrical performance of the memory device is the goal of continuous efforts.

### SUMMARY

The invention provides a memory structure and a manufacturing method thereof, which can improve the electrical performance of the memory structure.

The invention provides a memory structure, which includes a substrate, charge storage layers, and a gate. The charge storage layers are located on the substrate. The gate is located on the substrate on one side of the charge storage layers. The gate extends along a first direction. The gate has a protruding portion protruding along a second direction. The second direction intersects the first direction. The protruding portion is located between two adjacent charge storage layers arranged along the first direction.

According to an embodiment of the invention, the memory structure may further include dielectric layers. The dielectric layers are located between the charge storage layers and the substrate.

According to an embodiment of the invention, the memory structure may further include a dielectric layer. The dielectric layer is located between the gate and the substrate.

According to an embodiment of the invention, in the memory structure, the charge storage layers may be floating gates.

According to an embodiment of the invention, the memory structure may further include an isolation structure. The isolation structure is located in the substrate.

According to an embodiment of the invention, in the memory structure, there may be a trench in the isolation structure and between two adjacent charge storage layers arranged along the second direction. The trench may extend along the first direction.

According to an embodiment of the invention, in the memory structure, the isolation structure may have a recess between the two adjacent charge storage layers arranged along the first direction. The recess may be connected to the trench. The protruding portion may be located in the recess.

According to an embodiment of the invention, the memory structure may further include a hard mask layer. The hard mask layer is located on the charge storage layers and the isolation structure. The hard mask layer may extend along the first direction.

According to an embodiment of the invention, in the memory structure, the protruding portion may be located between the hard mask layer and the isolation structure.

According to an embodiment of the invention, the memory structure may further include a dielectric layer. The dielectric layer is located between the gate and the charge storage layers and between the gate and the isolation structure.

According to an embodiment of the invention, in the memory structure, the width of the protruding portion may be greater than 0 and less than or equal to 25 nm.

According to an embodiment of the invention, the memory structure may further include spacers. The spacers are located on the sidewalls of the charge storage layers away from the gate.

According to an embodiment of the invention, in the memory structure, the second direction may be perpendicular to the first direction.

The invention provides a manufacturing method of a memory structure, which includes the following steps. A substrate is provided. Charge storage layers are formed on the substrate. A gate is formed on the substrate on one side of the charge storage layers. The gate extends along a first direction. The gate has a protruding portion protruding along a second direction. The second direction intersects the first direction. The protruding portion is located between two adjacent charge storage layers arranged along the first direction.

According to an embodiment of the invention, the manufacturing method of the memory structure may further include the following step. Dielectric layers are formed between the charge storage layers and the substrate.

According to an embodiment of the invention, the manufacturing method of the memory structure may further include the following step. A dielectric layer is formed between the gate and the substrate.

According to an embodiment of the invention, the manufacturing method of the memory structure may further include the following step. An isolation structure is formed in the substrate.

According to an embodiment of the invention, in the manufacturing method of the memory structure, there may be a trench in the isolation structure and between two adjacent charge storage layers arranged along the second direction. The trench may extend along the first direction. The trench may expose the sidewall of the isolation structure.

According to an embodiment of the invention, in the manufacturing method of the memory structure, the method of forming the gate may include the following steps. A portion of the isolation structure exposed by the trench is removed to form a recess in the isolation structure. The portion of the isolation structure exposed by the trench is removed by a wet etching process. The gate is formed in the trench and the recess.

According to an embodiment of the invention, in the manufacturing method of the memory structure, the duration of the wet etching process may be 20 seconds to 130 seconds.

Based on the above description, in the memory structure and the manufacturing method thereof according to the invention, the gate has the protruding portion protruding along the second direction, and the protruding portion is located between two adjacent charge storage layers arranged along the first direction. Therefore, the on-current of the memory structure and the erasing capability when performing an erase operation on the memory structure can be improved, thereby improving the electrical performance of the memory structure.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a memory structure according to some embodiments of the invention.

FIG. 2A to FIG. 2P are cross-sectional views of a manufacturing process of a memory structure taken along section line I-I′ in FIG. 1.

FIG. 3A to FIG. 3P are cross-sectional views of a manufacturing process of a memory structure taken along section line II-II′ in FIG. 1.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

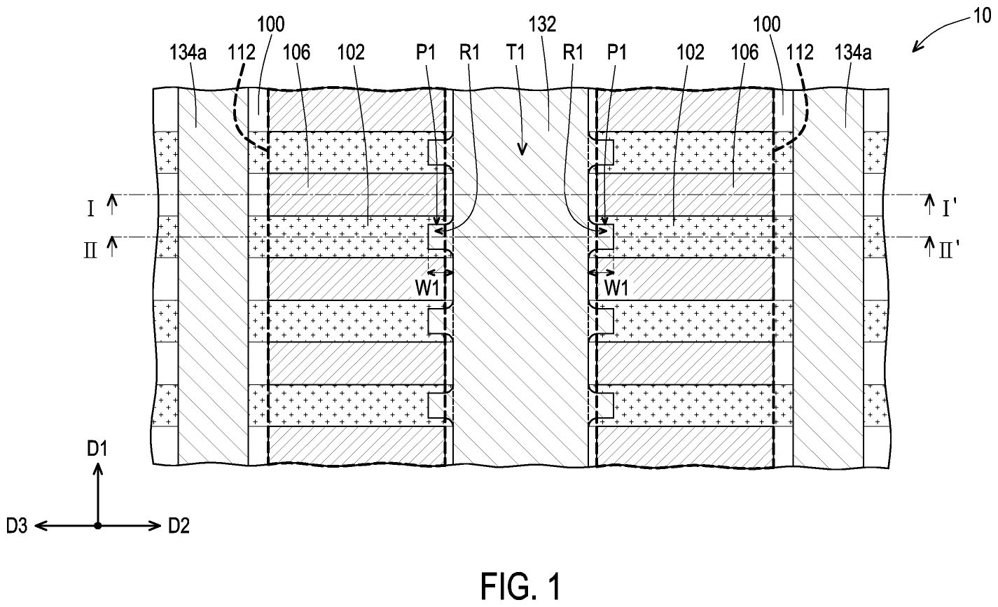

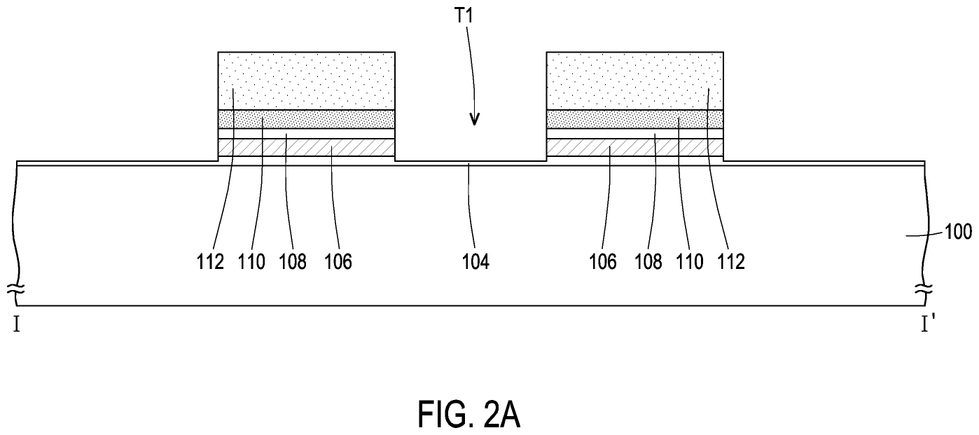

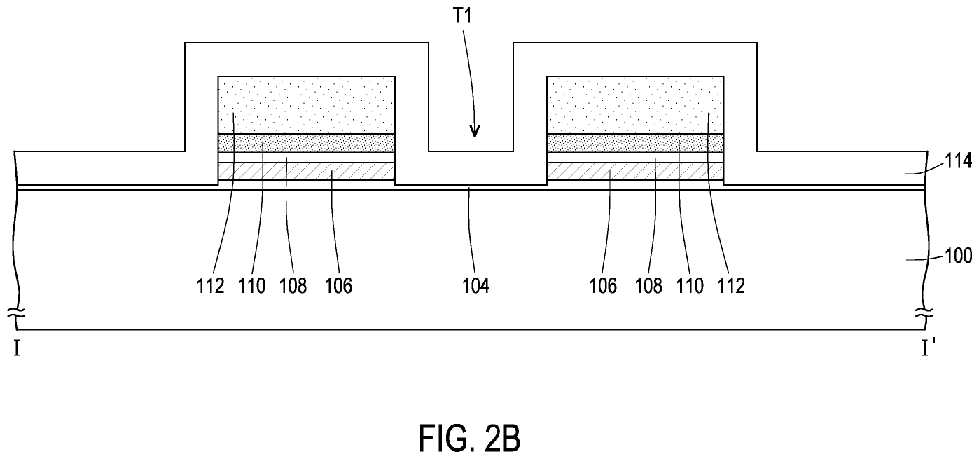

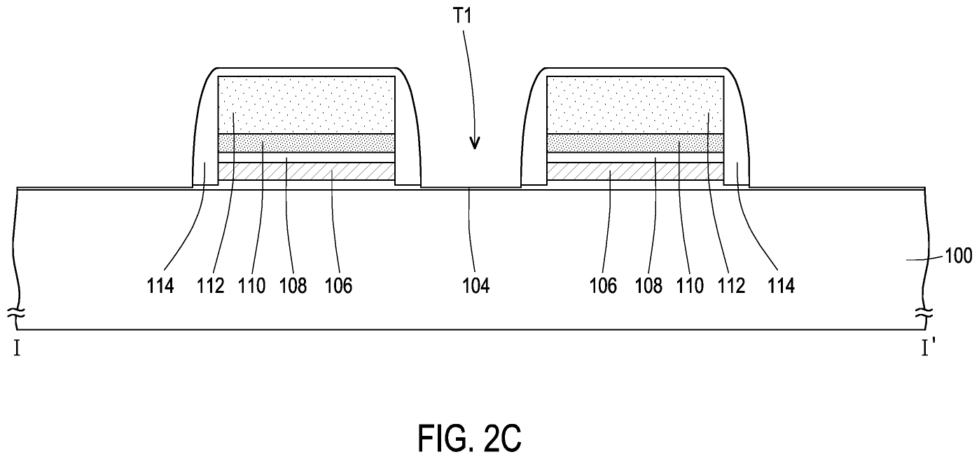

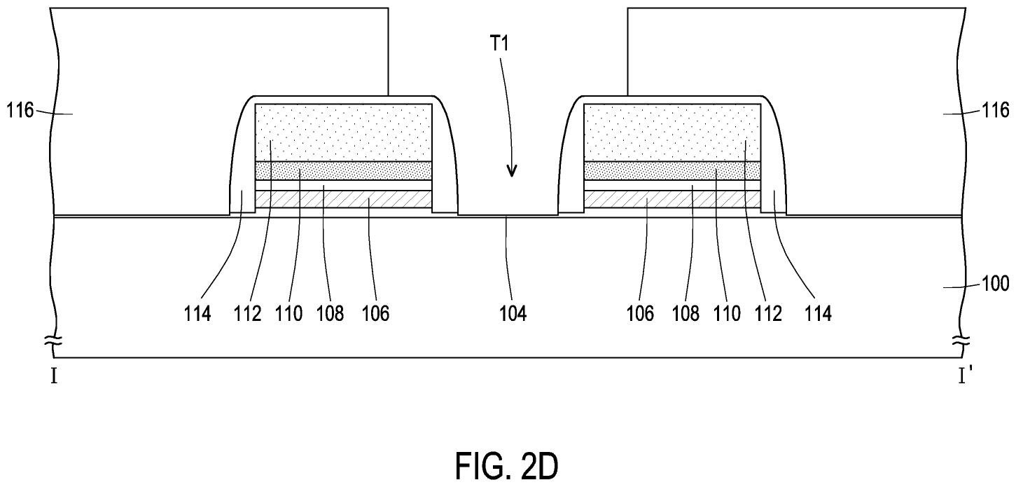

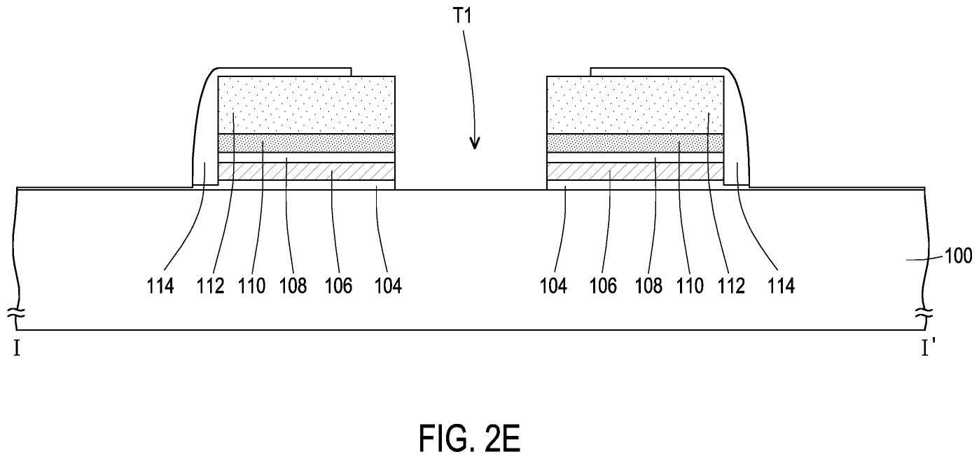

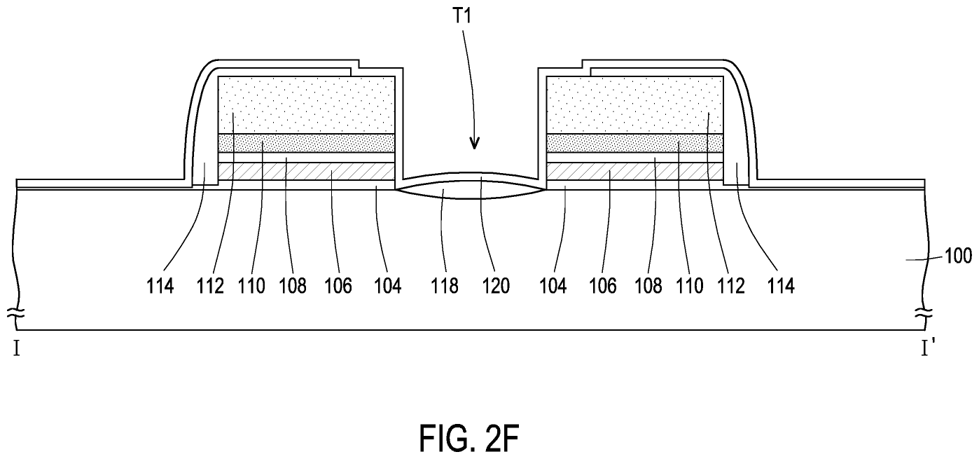

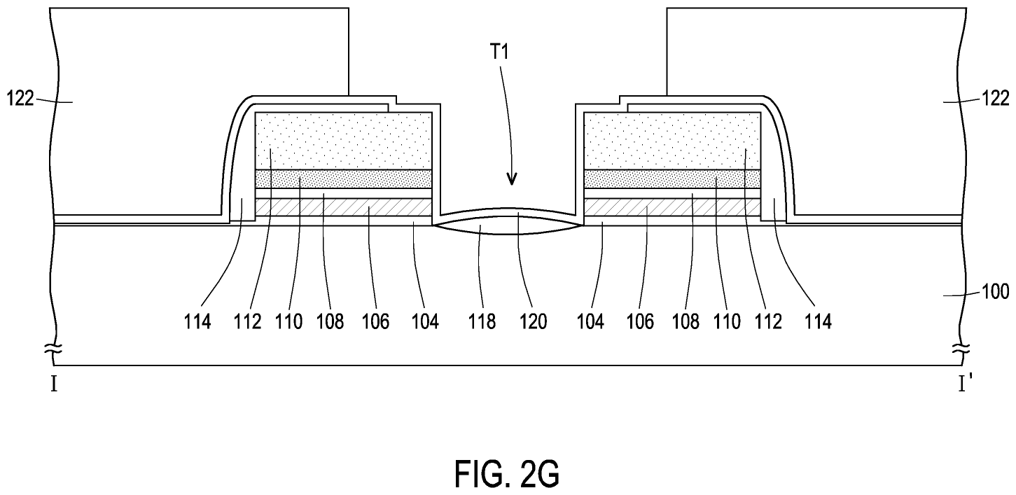

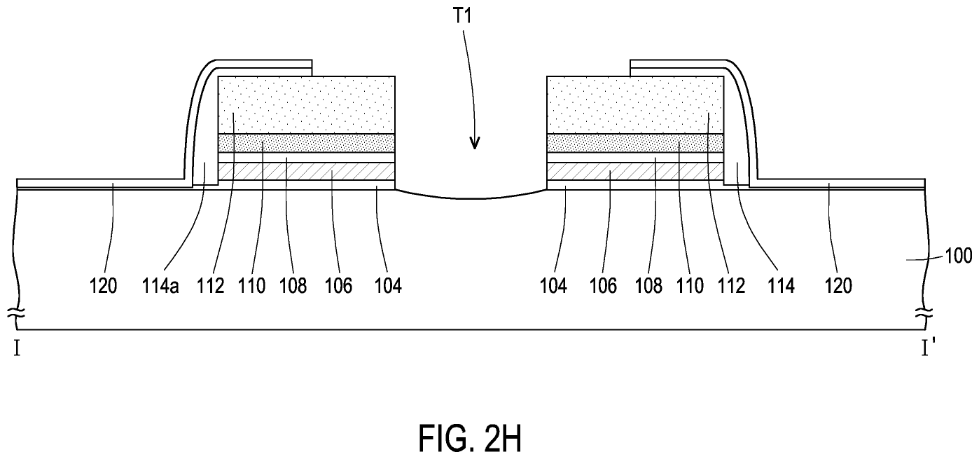

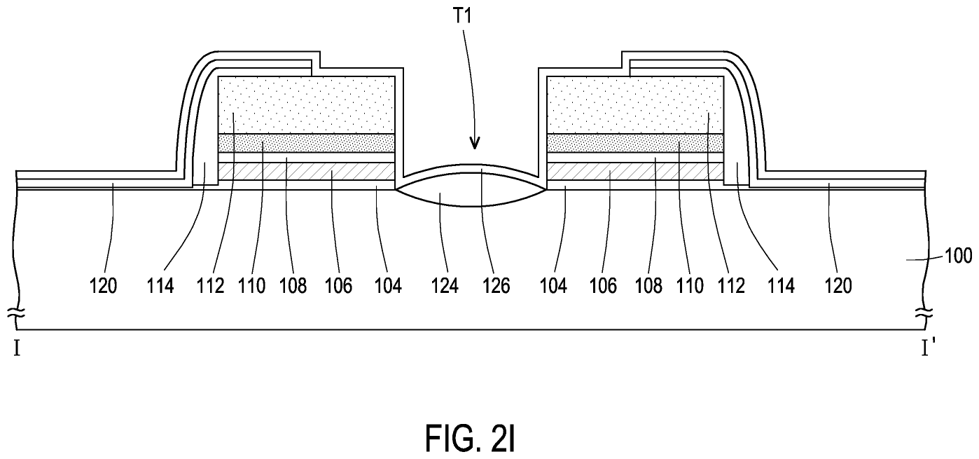

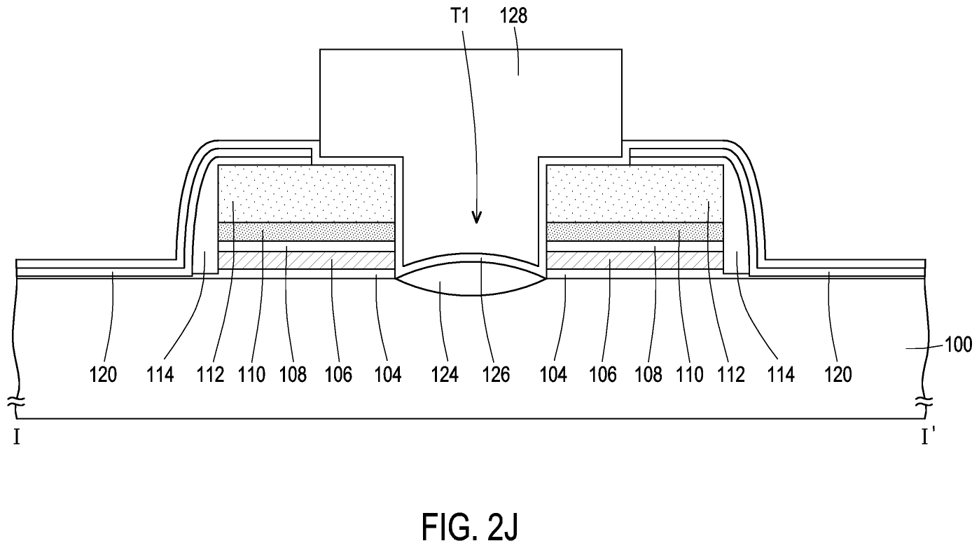

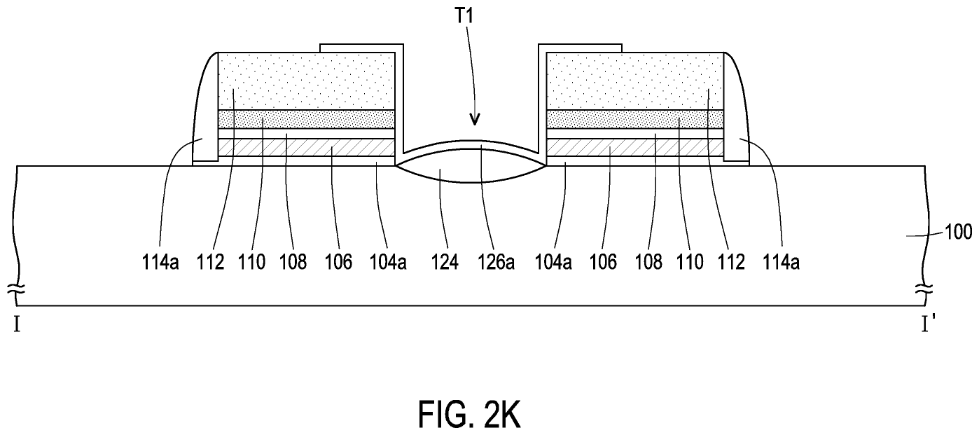

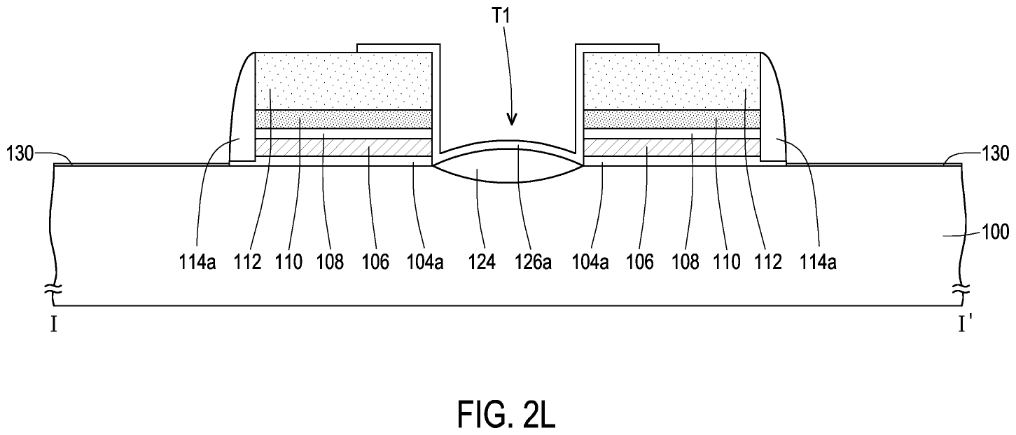

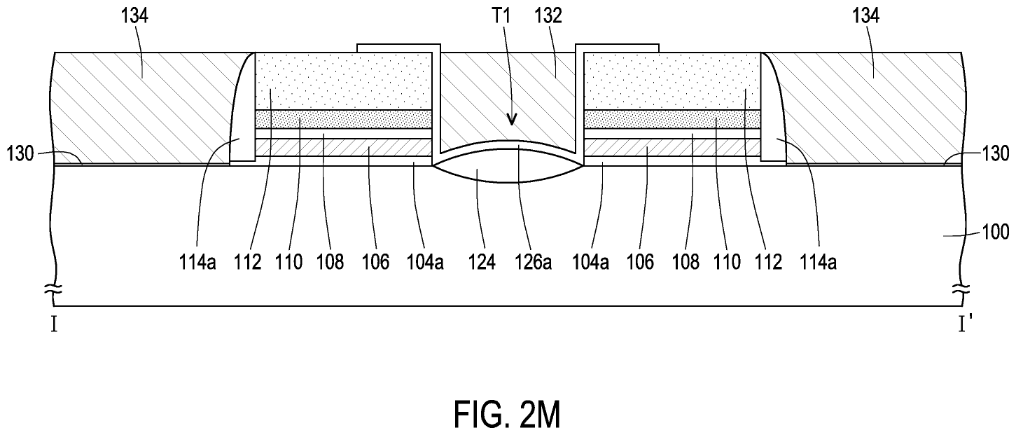

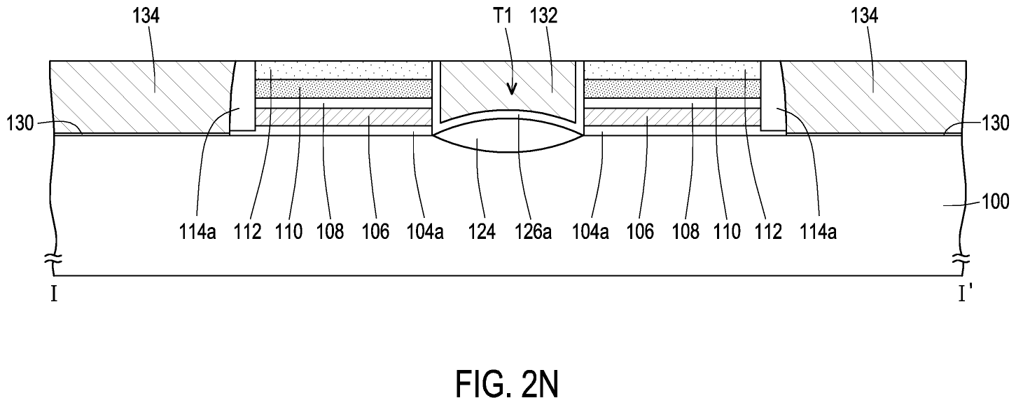

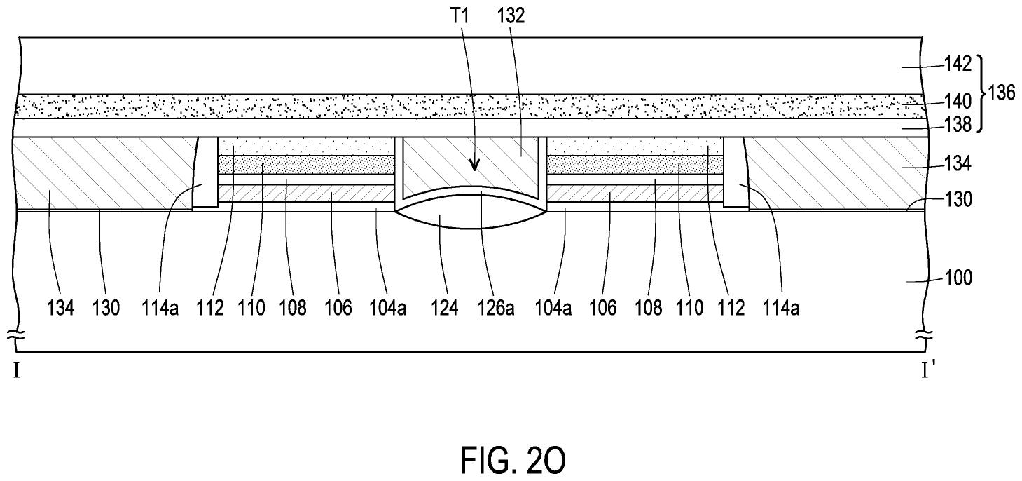

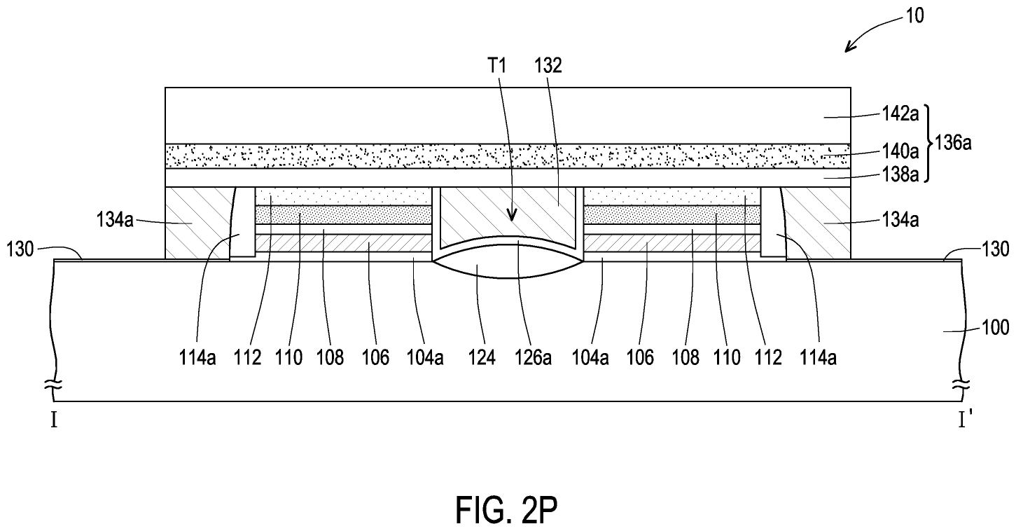

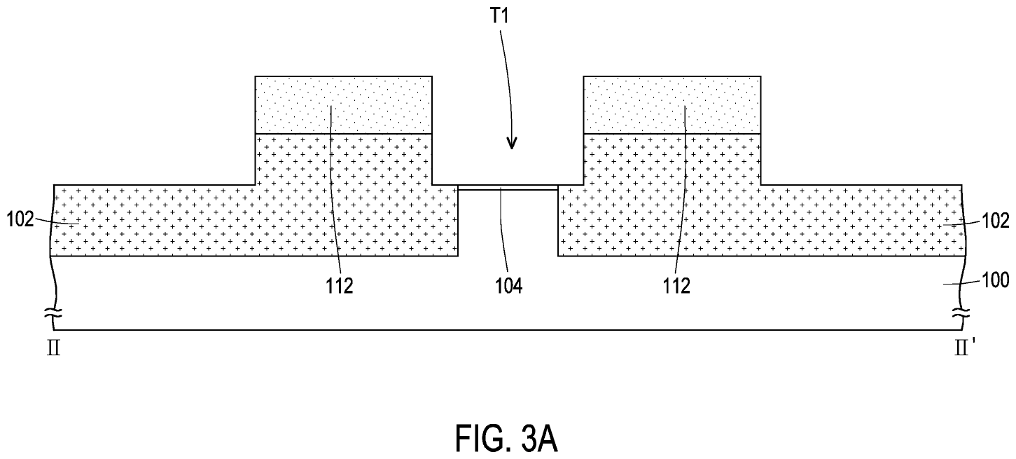

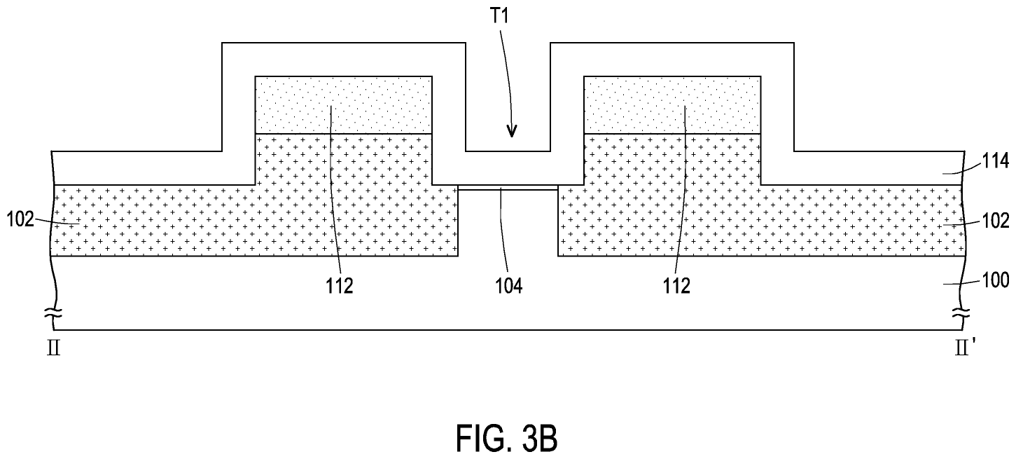

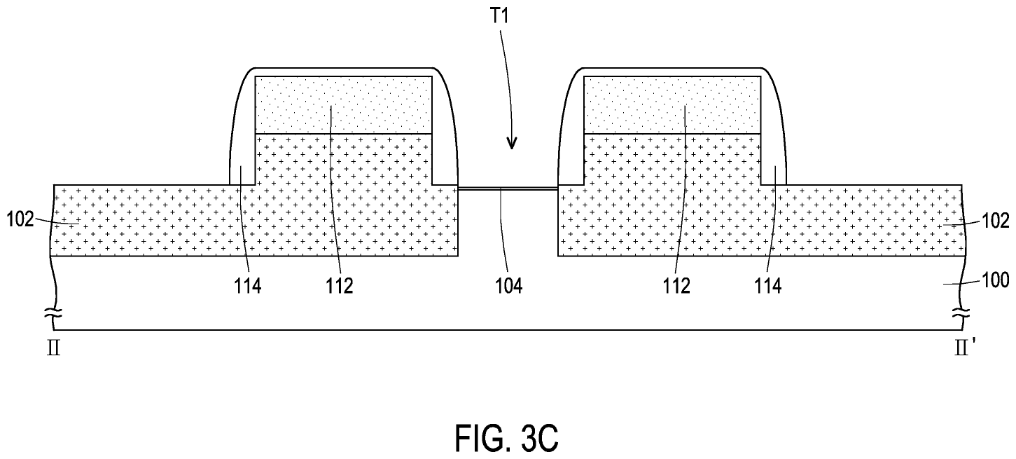

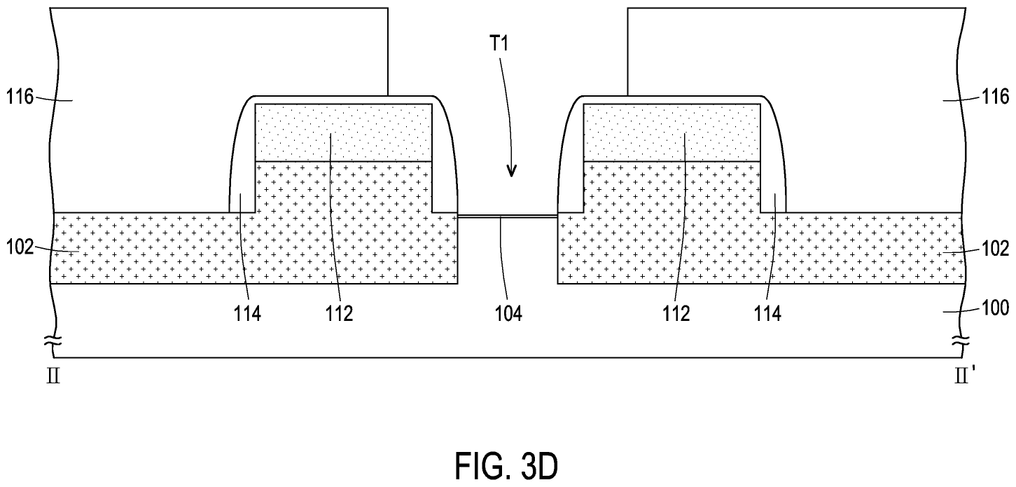

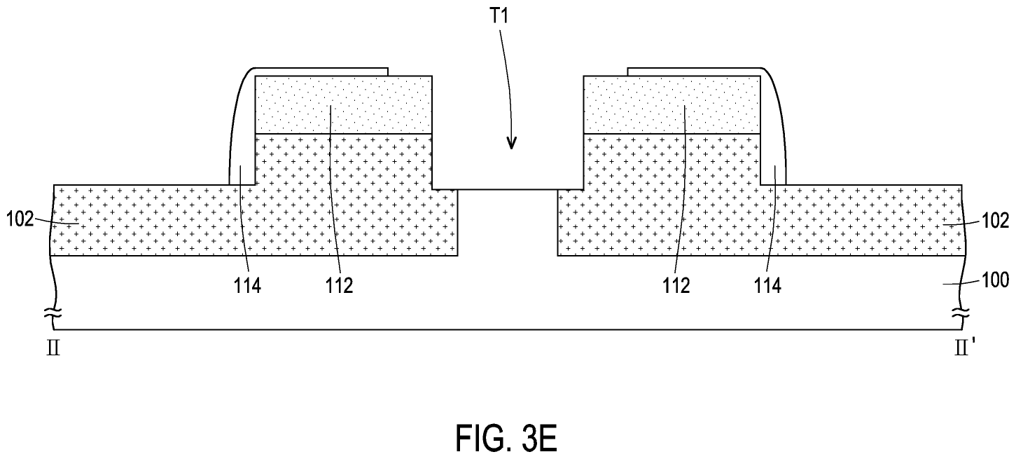

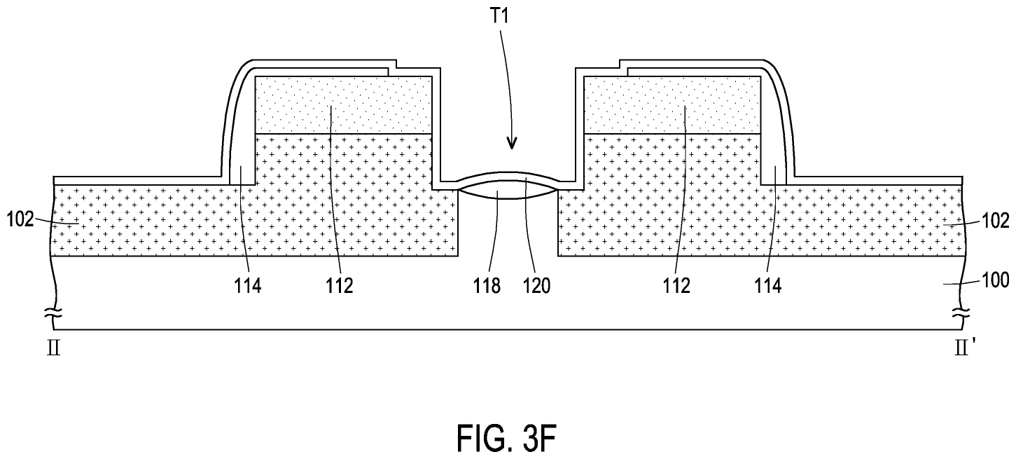

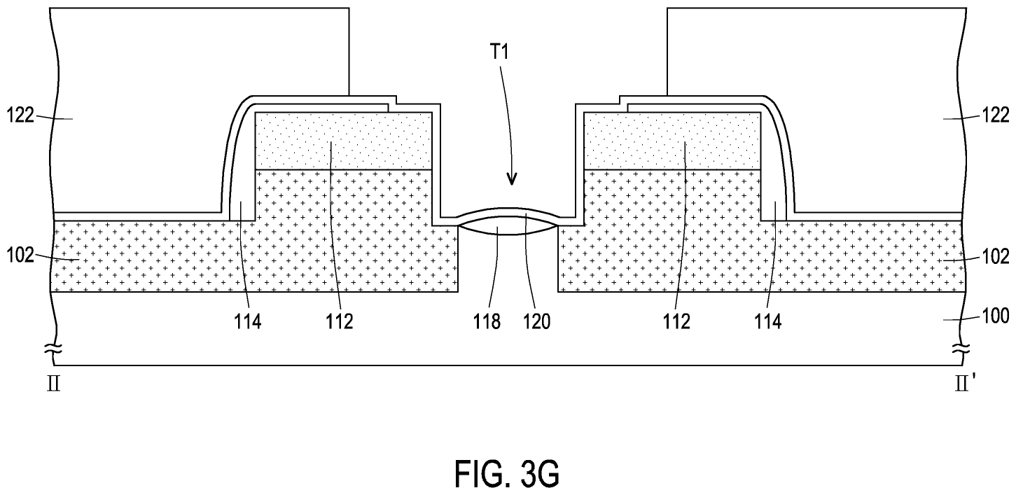

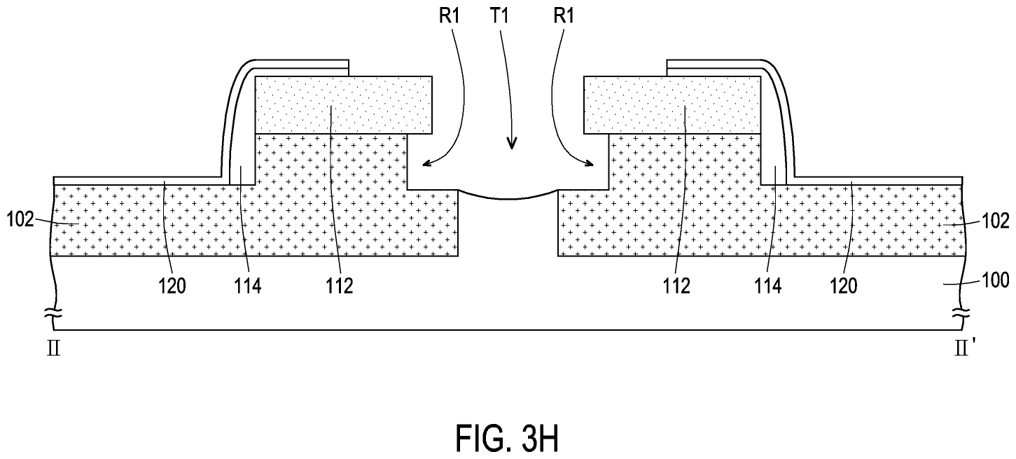

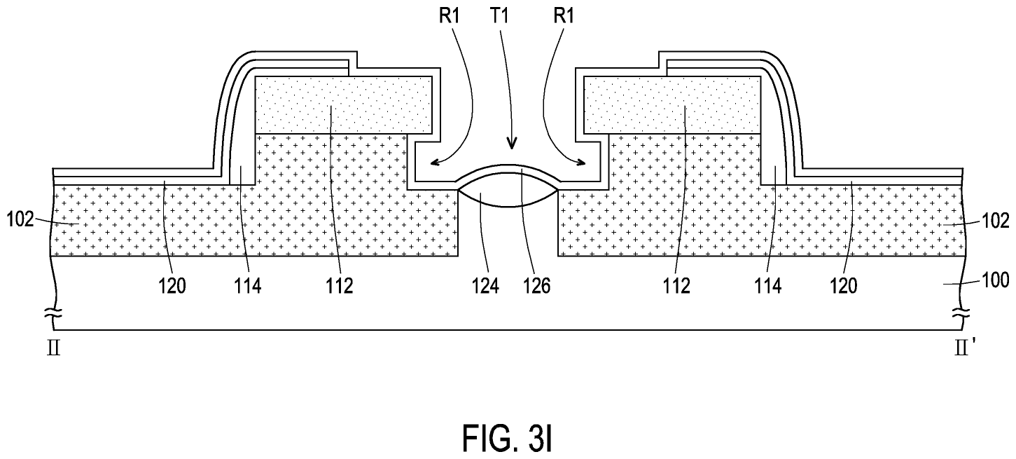

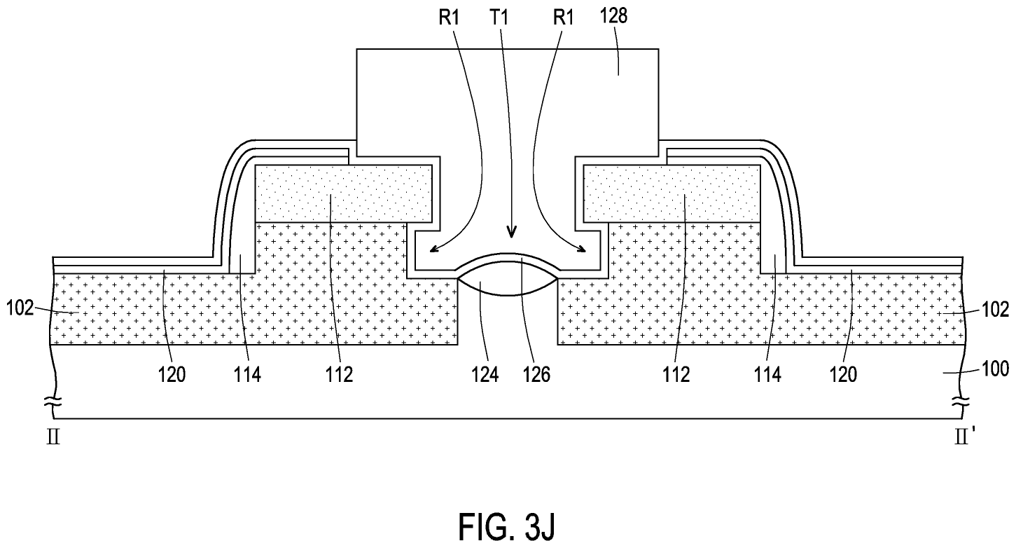

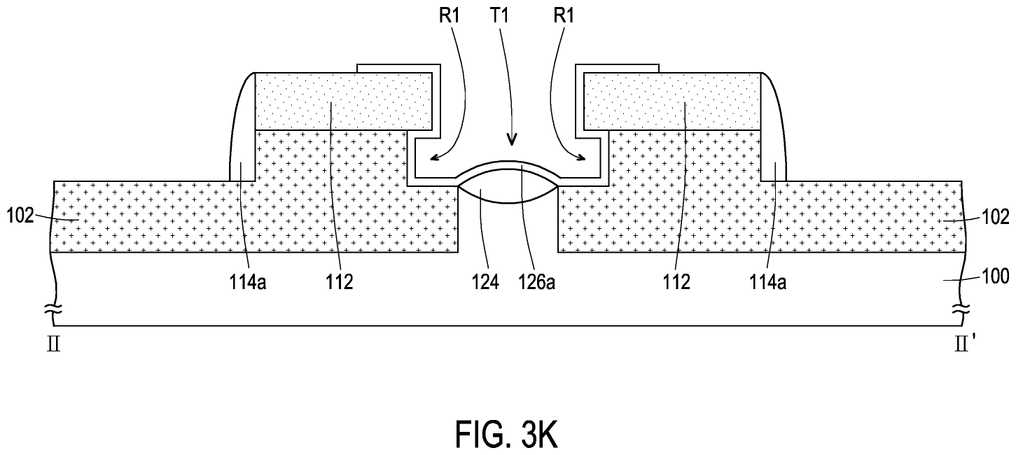

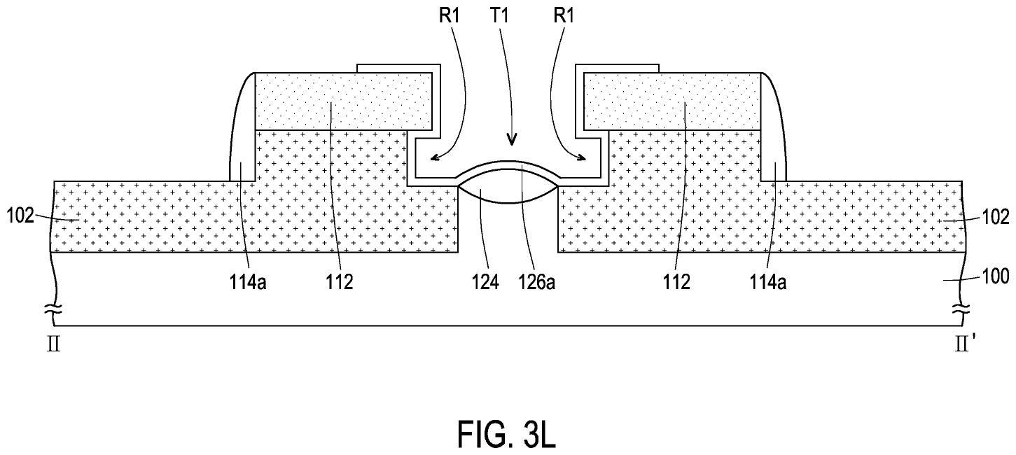

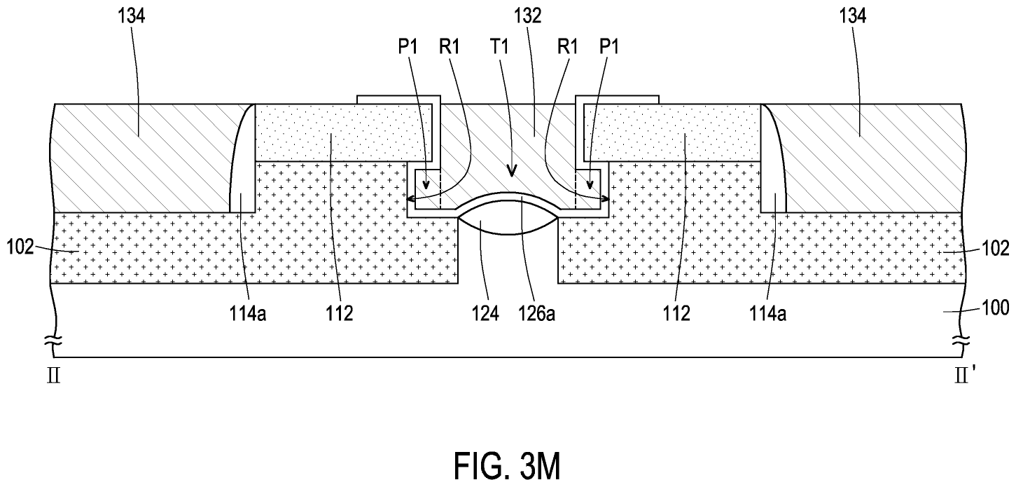

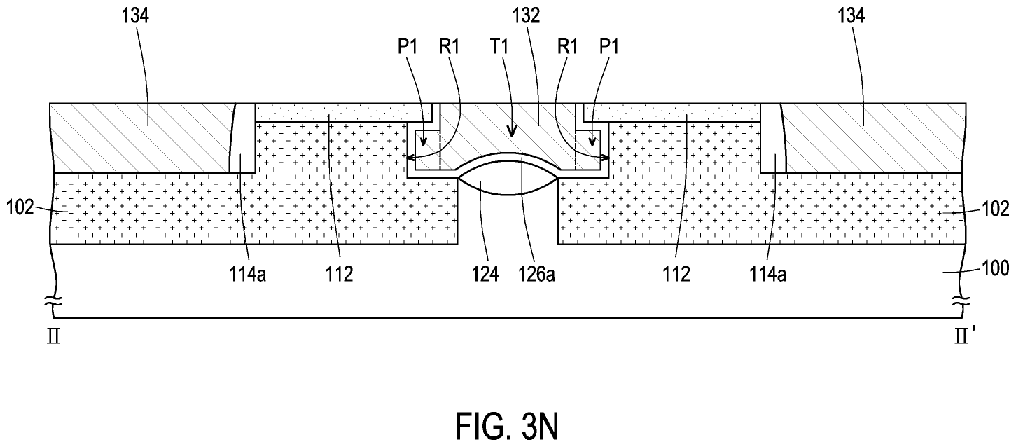

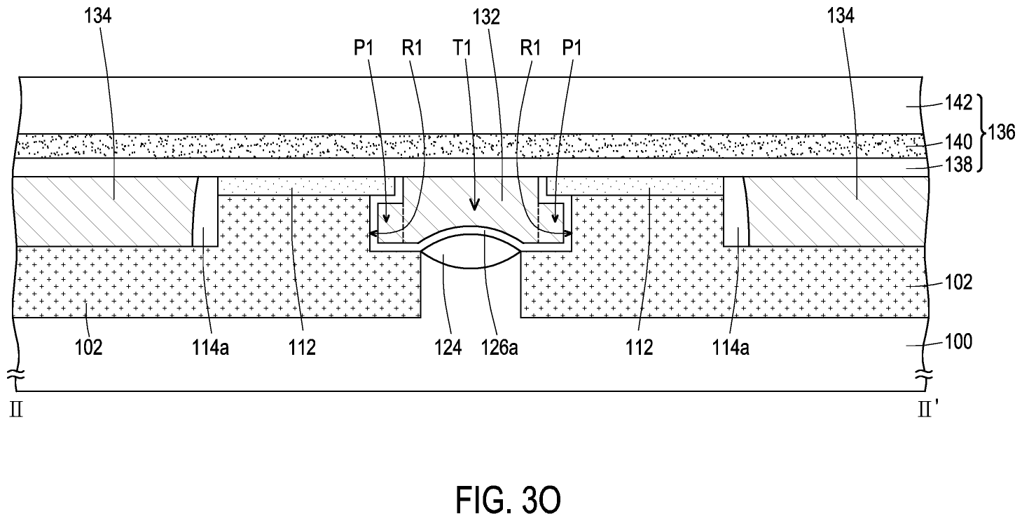

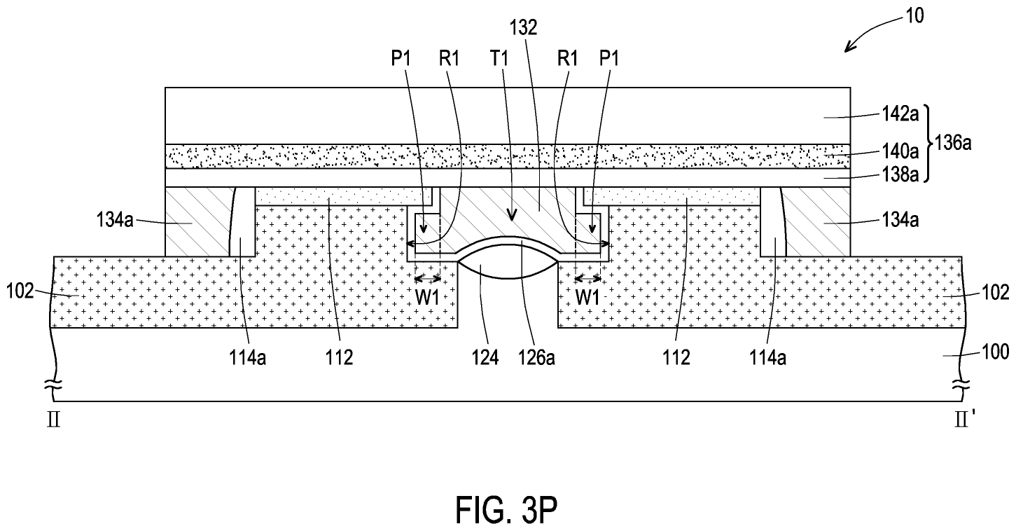

FIG. 1 is a top view of a memory structure according to some embodiments of the invention. FIG. 2A to FIG. 2P are cross-sectional views of a manufacturing process of a memory structure taken along section line I-I′ in FIG. 1. FIG. 3A to FIG. 3P are cross-sectional views of a manufacturing process of a memory structure taken along section line II-II′ in FIG. 1. In the top view of FIG. 1, some components in the cross-sectional views of FIG. 2P and FIG. 3P are omitted to clearly illustrate the configuration relationship between the components in the top view. In addition, in the top view of FIG. 1, the hard mask layer 112 is represented by a dotted line to clearly illustrate the configuration relationship between the components in the top view.

Referring to FIG. 2A and FIG. 3A, a substrate 100 is provided. The substrate 100 may be a semiconductor substrate such as a silicon substrate. In some embodiments, an isolation structure 102 may be formed in the substrate 100. The isolation structure 102 may be a shallow trench isolation (STI) structure. The material of the isolation structure 102 is, for example, silicon oxide. In some embodiments, a dielectric material layer 104 may be formed on the substrate 100. The material of the dielectric material layer 104, for example, is silicon oxide.

Charge storage layers 106 are formed on the substrate 100. In some embodiments, the charge storage layers 106 may be formed on the dielectric material layer 104. In some embodiments, as shown in FIG. 1, the charge storage layers 106 may be arranged along a first direction D1 and a second direction D2. The material of the charge storage layer 106 is, for example, doped polysilicon. In addition, there may be a trench T1 in the isolation structure 102 and between two adjacent charge storage layers 106 arranged along the second direction D2. The trench T1 may extend along the first direction D1. The trench T1 may expose the sidewall of the isolation structure 102.

In some embodiments, a hard mask layer 108 may be formed on the charge storage layer 106. The material of the hard mask layer 108 is, for example, silicon oxide. In some embodiments, a hard mask layer 110 may be formed on the hard mask layer 108. The material of the hard mask layer 110 is, for example, silicon nitride. In some embodiments, a hard mask layer 112 may be formed on the charge storage layers 106 and the isolation structures 102. In some embodiments, the hard mask layer 112 may be formed on the hard mask layer 110. In some embodiments, as shown in FIG. 1, the hard mask layer 112 may extend along the first direction D1. The material of the hard mask layer 112 is, for example, silicon nitride.

Referring to FIG. 2B and FIG. 3B, a spacer material layer 114 may be formed on the dielectric material layer 104, the charge storage layer 106, the hard mask layer 108, the hard mask layer 110, the hard mask layer 112, and the isolation structure 102. The material of the spacer material layer 114 is, for example, silicon oxide. The method of forming the spacer material layer 114 is, for example, a chemical vapor deposition (CVD) method.

Referring to FIG. 2C and FIG. 3C, a portion of the spacer material layer 114 may be removed to expose a portion of the dielectric material layer 104 and a portion of the isolation structure 102. A method of removing the portion of the spacer material layer 114 is, for example, a dry etching method.

Referring to FIG. 2D and FIG. 3D, a patterned photoresist layer 116 may be formed on the dielectric material layer 104, the spacer material layer 114, and the isolation structure 102. The patterned photoresist layer 116 may expose a portion of the dielectric material layer 104 and a portion of the spacer material layer 114. The patterned photoresist layer 116 may be formed by a lithography process.

Referring to FIG. 2E and FIG. 3E, a portion of the dielectric material layer 104 and a portion of the spacer material layer 114 may be removed by using the patterned photoresist layer 116 as a mask to expose a portion of the substrate 100 and a portion of the isolation structure 102. The method of removing the portion of the dielectric material layer 104 and the portion of the spacer material layer 114 is, for example, a wet etching method.

The patterned photoresist layer 116 may be removed. The method of removing the patterned photoresist layer 116 is, for example, a dry stripping method or a wet stripping method.

Referring to FIG. 2F and FIG. 3F, a dielectric layer 118 may be formed on the substrate 100. The material of the dielectric layer 118 is, for example, silicon oxide. The method of forming the dielectric layer 118 is, for example, a thermal oxidation method.

A dielectric layer 120 may be formed on the dielectric material layer 104, the charge storage layer 106, the hard mask layer 108, the hard mask layer 110, the hard mask layer 112, the spacer material layer 114, the dielectric layer 118, and the isolation structure 102. The material of the dielectric layer 120 is, for example, silicon oxide. The method of forming the dielectric layer 120 is, for example, a CVD method.

Referring to FIG. 2G and FIG. 3G, a patterned photoresist layer 122 may be formed on the dielectric layer 120. The patterned photoresist layer 122 may expose a portion of the dielectric layer 120. The patterned photoresist layer 122 may be formed by a lithography process.

Referring to FIG. 2H and FIG. 3H, a portion of the dielectric layer 120, the dielectric layer 118, a portion of the spacer material layer 114, and a portion of the isolation structure 102 may be removed by using the patterned photoresist layer 122 as a mask. Therefore, a portion of the substrate 100 may be exposed, and a portion of the isolation structure 102 exposed by the trench T1 may be removed to form a recess R1 in the isolation structure 102. The recess R1 may be connected to trench T1. In some embodiments, the portion of the dielectric layer 120, the dielectric layer 118, the portion of the spacer material layer 114, and the portion of the isolation structure 102 exposed by the trench T1 may be removed by a wet etching process. In some embodiments, the duration of the wet etching process may be 20 seconds to 130 seconds. In some embodiments, the duration of the wet etching process may be 65 seconds to 110 seconds.

The patterned photoresist layer 122 may be removed. The method of removing the patterned photoresist layer 122 is, for example, a dry stripping method or a wet stripping method.

Referring to FIG. 2I and FIG. 3I, a dielectric layer 124 may be formed on the substrate 100. The material of the dielectric layer 124 is, for example, silicon oxide. The method of forming the dielectric layer 124 is, for example, a thermal oxidation method.

A dielectric material layer 126 is formed on the dielectric material layer 104, the charge storage layer 106, the hard mask layer 108, the hard mask layer 110, the hard mask layer 112, the spacer material layer 114, the dielectric layer 120, the dielectric layer 124, and the isolation structure 102. The material of the dielectric material layer 126 is, for example, silicon oxide. The method of forming the dielectric material layer 126 is, for example, a CVD method.

Referring to FIG. 2J and FIG. 3J, a patterned photoresist layer 128 may be formed on the dielectric material layer 126. The patterned photoresist layer 128 may expose a portion of the dielectric material layer 126. The patterned photoresist layer 128 may be formed by a lithography process.

Referring to FIG. 2K and FIG. 3K, a portion of the dielectric material layer 126, the dielectric layer 120, a portion of the spacer material layer 114, and a portion of the dielectric material layer 104 may be removed by using the patterned photoresist layer 128 as a mask to form a dielectric layer 126a, a spacer 114a, and a dielectric layer 104a and to expose a portion of the substrate 100 and a portion of the isolation structure 102. Therefore, the dielectric layers 104a may be formed between the charge storage layers 106 and the substrate 100, and the spacer 114a may be formed on the sidewall of the charge storage layer 106, the sidewall of the hard mask layer 108, the sidewall of the hard mask layer 110, the sidewall of the hard mask layer 112, and the sidewall of the isolation structure 102. The method of removing the portion of the dielectric material layer 126, the dielectric layer 120, the portion of the spacer material layer 114, and the portion of the dielectric material layer 104 is, for example, a wet etching method.

The patterned photoresist layer 128 may be removed. The method of removing the patterned photoresist layer 128 is, for example, a dry stripping method or a wet stripping method.

Referring to FIG. 2L and FIG. 3L, a dielectric layer 130 may be formed on the substrate 100. The material of the dielectric layer 130 is, for example, silicon oxide. The method of forming the dielectric layer 130 is, for example, a thermal oxidation method.

Referring to FIG. 2M and FIG. 3M, a gate 132 may be formed in the trench T1 and the recess R1, and a conductive layer 134 may be formed on the dielectric layer 130 and the isolation structure 102. The gate 132 and the conductive layer 134 may be separated from each other. The gate 132 may have a protruding portion P1. The protruding portion P1 may be located in recess R1. In some embodiments, the gate 132 may be formed on the dielectric layer 126a. In some embodiments, the method of forming the gate 132 and the conductive layer 134 may include the following steps. First, a conductive material layer (not shown) may be formed on the dielectric layer 126a, the hard mask layer 112, the spacer 114a, the dielectric layer 130, and the isolation structure 102, and the conductive material layer may fill the trench T1 and the recess R1. Then, a chemical mechanical polishing (CMP) process may be performed on the conductive material layer to form the gate 132 and the conductive layer 134. The material of the gate 132 and the material of the conductive layer 134 are, for example, doped polysilicon.

By the above method, the gate 132 may be formed on the substrate 100 on one side of the charge storage layers 106, the dielectric layer 124 may be formed between the gate 132 and the substrate 100, and the dielectric layer 126a may be formed between the gate 132 and the dielectric layer 124. In addition, the dielectric layer 126a may be further formed between the gate 132 and the charge storage layer 106, between the gate 132 and the hard mask layer 108, between the gate 132 and the hard mask layer 110, between the gate 132 and the hard mask layer 112, and between the gate 132 and the isolation structure 102.

Referring to FIG. 2N and FIG. 3N, an etch back process may be performed on the gate 132, the conductive layer 134, the dielectric layer 126a, the hard mask layer 112, and the spacer 114a. The etch back process is, for example, a dry etch process.

Referring to FIG. 2O and FIG. 3O, a hard mask structure 136 may be formed on the gate 132, the conductive layer 134, the dielectric layer 126a, the hard mask layer 112, and the spacer 114a. The hard mask structure 136 may be a single-layer structure or a multilayer structure. In the present embodiment, the hard mask structure 136 is, for example, a multilayer structure. For example, the hard mask structure 136 may include a hard mask layer 138, a hard mask layer 140, and a hard mask layer 142. The hard mask layer 138 is located on the gate 132, the conductive layer 134, the dielectric layer 126a, the hard mask layer 112, and the spacer 114a. The material of the hard mask layer 138 is, for example, silicon oxide. The method of forming the hard mask layer 138 is, for example, a CVD method. The hard mask layer 140 is located on the hard mask layer 138. The material of the hard mask layer 140 is, for example, silicon nitride. The method of forming the hard mask layer 140 is, for example, a CVD method. The hard mask layer 142 is located on the hard mask layer 140. The material of the hard mask layer 142 is, for example, silicon oxide. The method of forming the hard mask layer 142 is, for example, a CVD method.

Referring to FIG. 2P and FIG. 3P, the hard mask structure 136 and the conductive layer 134 may be patterned to form a patterned hard mask structure 136a and a gate 134a. Therefore, the gate 134a may be formed on the dielectric layer 130 and the isolation structure 102. The patterned hard mask structure 136a may include a patterned hard mask layer 138a, a patterned hard mask layer 140a, and a patterned hard mask layer 142a. The patterned hard mask layer 138a is located on the gate 132, the gate 134a, the dielectric layer 126a, the hard mask layer 112, and the spacer 114a. The patterned hard mask layer 140a is located on the patterned hard mask layer 138a. The patterned hard mask layer 142a is located on the patterned hard mask layer 140a.

Hereinafter, the memory structure 10 of the above embodiments will be described with reference to FIG. 1, FIG. 2P, and FIG. 3P. In addition, although the method for forming the memory structure 10 is described by taking the above method as an example, the invention is not limited thereto.

Referring to FIG. 1, FIG. 2P, and FIG. 3P, the memory structure 10 includes a substrate 100, charge storage layers 106, and a gate 132. In some embodiments, the memory structure 10 may be a non-volatile memory structure such as a flash memory structure. The charge storage layers 106 are located on the substrate 100. In some embodiments, the charge storage layers 106 may be floating gates. The gate 132 is located on the substrate 100 on one side of the charge storage layers 106. In some embodiments, the gate 132 may be used as an erase gate. The gate 132 extends along a first direction D1. The gate 132 has a protruding portion P1 protruding along a second direction D2. In some embodiments, the gate 132 further has a protruding portion P1 protruding along a third direction D3 opposite to the second direction D2. The second direction D2 intersects the first direction D1. In some embodiments, the second direction D2 may be perpendicular to the first direction D1. The protruding portion P1 is located between two adjacent charge storage layers 106 arranged along the first direction D1. In some embodiments, the width W1 of the protruding portion P1 may be greater than 0 and less than or equal to 25 nm. In some embodiments, the width W1 of the protruding portion P1 may be 4 nm to 19 nm.

The memory structure 10 may further include an isolation structure 102. The isolation structure 102 is located in the substrate 100. There may be a trench T1 in the isolation structure 102 and between two adjacent charge storage layers 106 arranged along the second direction D2. The trench T1 may extend along the first direction D1. The isolation structure 102 may have a recess R1 between two adjacent charge storage layers 106 arranged along the first direction D1. The recess R1 may be connected to the trench T1. The protruding portion P1 may be located in the recess R1.

The memory structure 10 may further include dielectric layers 104a. The dielectric layers 104a are located between the charge storage layers 106 and the substrate 100. The memory structure 10 may further include a dielectric layer 124. The dielectric layer 124 is located between the gate 132 and the substrate 100. The memory structure 10 may further include a dielectric layer 126a. The dielectric layer 126a is located between the gate 132 and the dielectric layer 124. The dielectric layer 126a may be further located between the gate 132 and the charge storage layers 106 and between the gate 132 and the isolation structure 102.

The memory structure 10 may further include a hard mask layer 112. The hard mask layer 112 is located on the charge storage layers 106 and the isolation structures 102. The hard mask layer 112 may extend along the first direction D1. The protruding portion P1 may be located between the hard mask layer 112 and the isolation structure 102. The memory structure 10 may further include a hard mask layer 110. The hard mask layer 110 is located between the hard mask layer 112 and the charge storage layer 106. The memory structure 10 may further include a hard mask layer 108. The hard mask layer 108 is located between the hard mask layer 110 and the charge storage layer 106. In addition, the dielectric layer 126a may be further located between the gate 132 and the hard mask layer 108, between the gate 132 and the hard mask layer 110, and between the gate 132 and the hard mask layer 112. The memory structure 10 may further include spacers 114a. The spacers 114a are located on the sidewalls of the charge storage layers 106 away from the gate 132.

The memory structure 10 may further include a gate 134a and a dielectric layer 130. The gate 134a is located on one side of the charge storage layer 106 away from the gate 132. The gate 134a is located on the dielectric layer 130 and the isolation structure 102. In some embodiments, the gate 134a may be used as a select gate. The spacer 114a may be located between the gate 134a and the charge storage layer 106 and between the gate 134a and the isolation structure 102. The memory structure 10 may further include a patterned hard mask structure 136a. The patterned hard mask structure 136a may be a single-layer structure or a multilayer structure. In the present embodiment, the patterned hard mask structure 136a is, for example, a multilayer structure. For example, the patterned hard mask structure 136a may include a patterned hard mask layer 138a, a patterned hard mask layer 140a, and a patterned hard mask layer 142a. The patterned hard mask layer 138a is located on the gate 132, the gate 134a, the dielectric layer 126a, the hard mask layer 112, and the spacer 114a. The patterned hard mask layer 140a is located on the patterned hard mask layer 138a. The patterned hard mask layer 142a is located on the patterned hard mask layer 140a.

In some embodiments, there may be a control gate (not shown) above the charge storage layer 106, and the control gate and the charge storage layer 106 are insulated from each other, and the description thereof is omitted here. In some embodiments, the substrate 100 may have required doped regions (not shown) therein, and the description thereof is omitted here.

In addition, the details (e.g., the material and the forming method) of each component in the memory structure 10 have been described in detail in the above embodiments, and the description thereof is not repeated here.

Based on the above embodiments, in the memory structure 10 and the manufacturing method thereof, the gate 132 has the protruding portion P1 protruding along the second direction D2, and the protruding portion P1 is located between two adjacent charge storage layers 106 arranged along the first direction D1. Therefore, the on-current of the memory structure 10 and the erasing capability when performing an erase operation on the memory structure 10 can be improved, thereby improving the electrical performance of the memory structure 10.

In summary, in the memory structure and the manufacturing method thereof of the aforementioned embodiments, since the gate has a protruding portion, the on-current of the memory structure and the erasing capability when performing an erase operation on the memory structure can be improved, thereby improving the electrical performance of the memory structure.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A memory structure, comprising:
a substrate;
charge storage layers located on the substrate; and
a gate located on the substrate on one side of the charge storage layers and extending along a first direction, wherein the gate has a protruding portion protruding along a second direction, the second direction intersects the first direction, and the protruding portion is located between two adjacent charge storage layers arranged along the first direction.

2. The memory structure according to claim 1, further comprising:
dielectric layers located between the charge storage layers and the substrate.

3. The memory structure according to claim 1, further comprising:
a dielectric layer located between the gate and the substrate.

4. The memory structure according to claim 1, wherein the charge storage layers comprise floating gates.

5. The memory structure according to claim 1, further comprising:
an isolation structure located in the substrate.

6. The memory structure according to claim 5, wherein there is a trench in the isolation structure and between two adjacent charge storage layers arranged along the second direction, and the trench extends along the first direction.

7. The memory structure according to claim 6, wherein
the isolation structure has a recess between the two adjacent charge storage layers arranged along the first direction,
the recess is connected to the trench, and
the protruding portion is located in the recess.

8. The memory structure according to claim 5, further comprising:
a hard mask layer located on the charge storage layers and the isolation structure, wherein the hard mask layer extends along the first direction.

9. The memory structure according to claim 8, wherein the protruding portion is located between the hard mask layer and the isolation structure.

10. The memory structure according to claim 5, further comprising:
a dielectric layer located between the gate and the charge storage layers and between the gate and the isolation structure.

11. The memory structure according to claim 1, wherein a width of the portion protruding is greater than 0 and less than or equal to 25 nm.

12. The memory structure according to claim 1, further comprising:
spacers located on sidewalls of the charge storage layers away from the gate.

13. The memory structure according to claim 1, wherein the second direction is perpendicular to the first direction.

14. A manufacturing method of a memory structure, comprising:
providing a substrate;
forming charge storage layers on the substrate; and
forming a gate on the substrate on one side of the charge storage layers, wherein the gate extends along a first direction, the gate has a protruding portion protruding along a second direction, the second direction intersects the first direction, and the protruding portion is located between two adjacent charge storage layers arranged along the first direction.

15. The manufacturing method of the memory structure according to claim 14, further comprising:
forming dielectric layers between the charge storage layers and the substrate.

16. The manufacturing method of the memory structure according to claim 14, further comprising:
forming a dielectric layer between the gate and the substrate.

17. The manufacturing method of the memory structure according to claim 14, further comprising:
forming an isolation structure in the substrate.

18. The manufacturing method of the memory structure according to claim 17, wherein
there is a trench in the isolation structure and between two adjacent charge storage layers arranged along the second direction,
the trench extends along the first direction, and
the trench exposes a sidewall of the isolation structure.

19. The manufacturing method of the memory structure according to claim 18, wherein a method of forming the gate comprises:
removing a portion of the isolation structure exposed by the trench to form a recess in the isolation structure, wherein the portion of the isolation structure exposed by the trench is removed by a wet etching process; and
forming the gate in the trench and the recess.

20. The manufacturing method of the memory structure according to claim 19, wherein a duration of the wet etching process is 20 seconds to 130 seconds.
